(19) United States
(12) Patent Application Publication
(10) Pub. No.: US 2024/0298409 A1
(43) Pub. Date: Sep. 5, 2024

(54) CIRCUIT BOARD, MANUFACTURING METHOD THEREOF, AND ELECTRONIC COMPONENT PACKAGE INCLUDING THE SAME

(71) Applicant: SAMSUNG ELECTRO-MECHANICS CO., LTD., Suwon-si (KR)

(72) Inventors: Jong-Seok Na, Suwon-si (KR); Yunje Ji, Suwon-si (KR); Yonghoon Kim, Suwon-si (KR); Seungeun Lee, Suwon-si (KR)

(73) Assignee: SAMSUNG ELECTRO-MECHANICS CO., LTD., Suwon-si (KR)

(21) Appl. No.: 18/386,963

(22) Filed: Nov. 3, 2023

(30) Foreign Application Priority Data
Mar. 2, 2023 (KR) 10-2023-0027847

(51) Int. Cl. H05K 1/18; H05K 3/40; H05K 3/46

(52) U.S. Cl. CPC H05K 1/181; H05K 1/185; H05K 3/4007; H05K 3/4697; H05K 3/0017

(57) ABSTRACT

The present disclosure provides a circuit board including: an insulating layer; a circuit wire disposed in a first area inside the insulating layer, a first conductive pad connected to the circuit wire and having an upper surface protruding above an upper surface of the insulating layer and a lower surface embedded in the insulating layer; and a circuit element disposed to have a boundary surface parallel to the upper surface of the insulating layer in a second area different from the first area inside the insulating layer and including an element pad.

### CROSS-REFERENCE TO RELATED APPLICATION

This application claims priority to and the benefit of Korean Patent Application No. 10-2023-0027847 filed in the Korean Intellectual Property Office on Mar. 2, 2023, the entire contents of which are incorporated herein by reference.

### TECHNICAL FIELD

The present disclosure relates to a circuit board, a manufacturing method thereof, and an electronic component package including the same.

Recently, efforts have been made to improve a power delivery network (PDN) and implement a thin-film package in order to implement a high-performance mobile central processing unit (CPU). To this end, an embedding structure based on a coreless structure without a core member is being developed, and in particular, efforts are being made to reduce a path between a die and a capacitor to improve the power delivery network.

In order to reduce the path between the die and the capacitor, the die and the capacitor are directly connected, and recently, a structure for directly connecting a die and a silicon capacitor is being developed. However, since a width of a pad of the silicon capacitor and a width of a bump pad on a circuit board for connection to the die are different from each other, it is difficult to secure bonding reliability between the pads.

In addition, in order to reduce a thickness of the circuit board, a cavity is formed in a core board having a core member, and a passive element such as a capacitor is embedded in the cavity. However, in the case of the core substrate, since the core member has a predetermined thickness, there is a limit in minimizing the thickness of the circuit board.

### SUMMARY

The present disclosure provides a circuit board, a manufacturing method thereof, and an electronic component package including the same that may minimize a thickness of a circuit board and secure reliability.

However, the problems to be solved by embodiments are not limited to the above-described problem and may be variously extended in a range of technical ideas included in embodiments.

An embodiment provides a circuit board including: an insulating layer; a circuit wire disposed in a first area inside the insulating layer; a first conductive pad connected to the circuit wire and having an upper surface protruding above an upper surface of the insulating layer and a lower surface embedded in the insulating layer; and a circuit element disposed in a second area different from the first area inside the insulating layer and including an element pad, wherein an extension line of an upper surface of the first conductive pad and an upper surface of the element pad are spaced apart from each other along a direction perpendicular to an upper surface of the insulating layer, and based on the direction perpendicular to the upper surface of the insulating layer, an upper surface of the first conductive pad is disposed on the upper surface of the insulating layer, and an upper surface of the element pad is disposed below the upper surface of the insulating layer.

A layer on which the circuit element is disposed in the second area and a layer on which a portion of the circuit wire is disposed in the first area may be disposed on the same layer.

A width of the element pad may be wider than a width of the first conductive pad.

The circuit element may further include an element main body in which the element pad is disposed on an upper surface thereof, and an element insulating layer disposed on the element main body and having a first opening exposing the element pad.

Based on an upper surface of the element main body, a height of an upper surface of the first conductive pad may be higher than a height of an upper surface of the element pad.

The circuit element may be disposed to have a boundary surface parallel to the upper surface of the insulating layer in the second area, and at least a portion of the circuit wire may be disposed on the same layer as the boundary surface.

The circuit board may further include a second conductive pad connected to the circuit wire and protruding below a lower surface of the insulating layer, and a first solder resist layer covering the lower surface of the insulating layer and having a second opening exposing the second conductive pad.

The circuit board may further include a second solder resist layer covering the upper surface of the insulating layer and having a third opening exposing the first conductive pad.

The circuit element may include an integrated passive element.

Another embodiment provides a manufacturing method of a circuit board, including: sequentially forming a barrier layer and a first conductive pad on a carrier substrate; forming a first layer unit covering the first conductive pad and including a first insulating layer and a first circuit wire disposed within the first insulating layer, on the barrier layer; forming a cavity in one area of the first layer unit; disposing a circuit element in the cavity and adhering an element pad of the circuit element to the barrier layer by using an adhesive member; forming a second layer unit including a second insulating layer filling the cavity on the first layer unit and a second circuit wire disposed within the second insulating layer; separating the carrier substrate from the barrier layer; and sequentially etching the barrier layer, the adhesive member, and the upper surface of the first insulating layer to have the first conductive pad protrude above the upper surface of the first insulating layer.

The adhesive member may cover the element main body, and may adhere an element insulating layer having a first opening exposing the element pad, and the barrier layer.

The manufacturing method of the circuit board may further include forming a second conductive pad connected to the second circuit wire on the second insulating layer, and forming a first solder resist layer having a second opening exposing the second conductive pad on the second insulating layer.

A width of the element pad may be wider than a width of the first conductive pad.

A cavity may be formed in the first layer unit to expose the barrier layer.

Another embodiment provides an electronic component package, including: a circuit board that includes: an insulating layer; a circuit wire disposed in a first area inside the insulating layer; a first conductive pad connected to the circuit wire and having an upper surface protruding above an upper surface of the insulating layer and a lower surface embedded in the insulating layer; and a circuit element disposed in a second area different from the first area inside the insulating layer and including an element pad; an electronic component disposed on the circuit board; and a conductive adhesive member installed on the electronic component and electrically connected to the first conductive pad and the element pad, wherein an extension line of an upper surface of the first conductive pad and an upper surface of the element pad are spaced apart from each other along a direction perpendicular to an upper surface of the insulating layer, and based on the direction perpendicular to the upper surface of the insulating layer, an upper surface of the first conductive pad is disposed on the upper surface of the insulating layer, and an upper surface of the element pad is disposed below the upper surface of the insulating layer.

The conductive adhesive member may include a bump disposed to cover a signal wire of the electronic component, a first adhesive member that adheres the bump and the first conductive pad to each other, and a second adhesive member that adheres the bump and the element pad to each other, and a maximum width of the second adhesive member may be wider than a maximum width of the first adhesive member.

A layer on which the circuit element is disposed in the second area and a layer on which a portion of the circuit wire is disposed in the first area may be disposed on the same layer.

A width of the element pad may be wider than a width of the first conductive pad.

According to some embodiments of the present disclosure, it is possible to minimize a thickness of a circuit board by embedding a passive element in a coreless substrate having a thin thickness. Accordingly, thinning of an electronic component package including a circuit board may be easily implemented.

In addition, since an element pad of a passive element embedded in an insulating layer is exposed to the outside of a circuit board, a circuit element may be directly connected to a wire of an electronic component. Accordingly, reliability of the circuit element may be easily secured.

In addition, by forming a step between an element pad of a circuit element directly connected to an electronic component and a conductive pad of a circuit board, reliability of the conductive adhesive member may be ensured by ensuring that an amount of an adhesive member attached to the element pad is larger than an amount of an adhesive member attached to the conductive pad.

In addition, by adjusting a thickness of an adhesive member, it is possible to easily adjust a step between an element pad of a circuit element electrically connected to an electronic component and a conductive pad of a circuit board.

In addition, since a cavity may be simultaneously formed in a process of forming a via hole without performing a separate process for forming the cavity for disposing a circuit element, a manufacturing cost may be reduced by simplifying a manufacturing process.

It is obvious that the effect of the embodiments is not limited to the above-described effect, and may be variously extended without departing from the spirit and scope of the present disclosure.

### BRIEF DESCRIPTION OF THE DRAWINGS

FIG. 1 illustrates a cross-sectional view of a circuit board according to an embodiment.

FIG. 2 illustrates a cross-sectional view of an electronic component package including the circuit board of FIG. 1.

FIG. 3 to FIG. 7 illustrate sequential cross-sectional views of a manufacturing method of a circuit board according to an embodiment.

FIG. 8 illustrates a cross-sectional view of a circuit board according to another embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, the accompanying drawings are provided only in order to allow embodiments disclosed in the present specification to be easily understood and are not to be interpreted as limiting the spirit disclosed in the present specification, and it is to be understood that the present embodiments includes all modifications, equivalents, and substitutions without departing from the scope and spirit of the present disclosure.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

Hereinafter, various embodiments and variations will be described in detail with reference to the drawings.

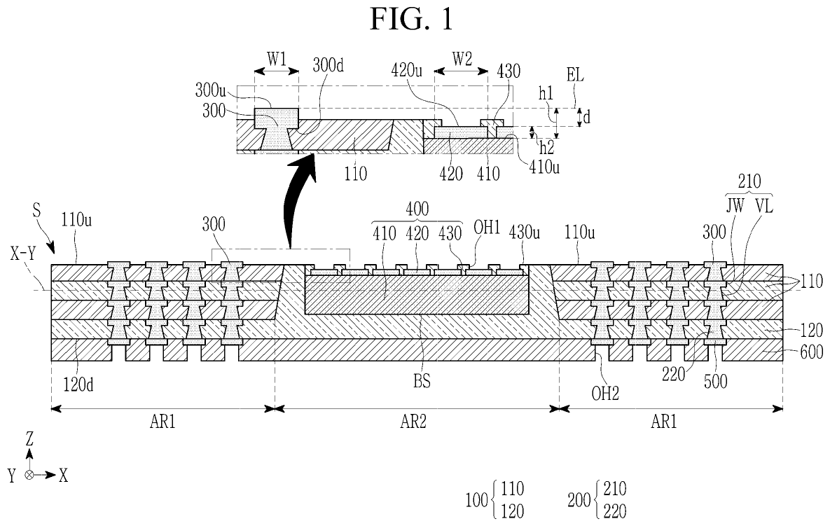

FIG. 1 illustrates a cross-sectional view of a circuit board according to an embodiment.

As shown in FIG. 1, a circuit board according to some embodiments includes an insulating layer 100, a circuit wire 200, a first conductive pad 300, a circuit element 400, a second conductive pad 500, and a first solder resist layer 600.

The insulating layer 100 may include a thermosetting resin at least one selected from the group consisting of: an epoxy resin, a polyimide, a thermoplastic resin such as polyethylene (PE), polycarbonate (PC), or polyvinyl chloride (PVC), a resin containing a reinforcing material such as a glass fiber or an inorganic filler, and combinations thereof. For example, the insulating layer 100 may include a prepreg, an Ajinomoto buildup film (ABF), a photo image-able Dielectric (PID), or combinations thereof.

The insulating layer 100 may include a first insulating layer 110 and a second insulating layer 120. The first conductive pad 300 protrudes on an upper surface 110u of the first insulating layer 110, and the circuit wire 200 and the first conductive pad 300 may be disposed inside the first insulating layer 110. The second conductive pad 500 is disposed inside the second insulating layer 120, and the second insulating layer 120 may contact the first solder resist layer 600.

The circuit wire 200 is disposed in a first area AR1 inside the first insulating layer 110, and may transmit an electrical signal. The circuit wire 200 may be disposed in various patterns. The circuit wire 200 may include a conductive material at least one selected from the group consisting of copper (Cu), aluminum (Al), silver (Ag), tin (Sn), gold (Au), nickel (Ni), lead (Pb), titanium (Ti), and an alloy thereof.

The circuit wire 200 may include a first circuit wire 210 and a second circuit wire 220. The first circuit wire 210 may be electrically connected to the first conductive pad 300 and may be disposed inside the first insulating layer 110. The second circuit wire 220 may be electrically connected to the second conductive pad 500 and may be disposed inside the second insulating layer 120. In the present embodiment, the first circuit wire 210 is illustrated as three layers, but is not limited thereto, and may be disposed with various numbers of layers. Here, the first circuit wire 210 includes a via layer VL having a tapered side surface and surface wire SW disposed on the via layer VL.

Here, since the insulating layer 100 and the circuit wire 200 do not include a separate core member, a thin coreless substrate may be obtained.

The first conductive pad 300 may be connected to the first circuit wire 210, and may protrude from an upper surface 110u of the first insulating layer 110. That is, an upper surface 300u of the first conductive pad 300 may protrude from the upper surface 110u of the first insulating layer 110, and a lower surface 300d of the first conductive pad 300 may be embedded inside the first insulating layer 110. The first conductive pad 300 may include at least one selected from the group consisting of copper (Cu), gold (Au), silver (Ag), nickel (Ni), and the combinations thereof.

The circuit element 400 may be disposed in a second area AR2 different from a first area AR1 in the first insulating layer 110. The circuit element 400 and the first insulating layer 110 may have a boundary surface BS, and may contact each other. The boundary surface BS may be substantially parallel to the upper surface 110u of the first insulating layer 110. The first circuit wire 210 may be disposed on the same layer as the boundary surface BS.

The circuit element 400 may include an integrated passive device (IPD) such as a silicon capacitor (Si-capacitor), a silicon bridge (Si-bridge), and a ceramic capacitor.

Here, the layer on which the circuit element 400 is disposed in the second area AR2 and the layer on which the first circuit wire 210 is disposed in the first area AR1 may be the same layer, for example, on the same plane (X-Y plane).

The circuit element 400 may include an element main body 410, an element pad 420, and an element insulating layer 430.

The element main body 410 may be a main portion of the circuit element 400 in which a driving circuit of the circuit element 400 is disposed.

The element pad 420 may be electrically connected to the element main body 410 and may be disposed on the upper surface 410u of the element main body 410.

Here, an extension line EL of the upper surface 300u of the first conductive pad 300 and an upper surface 420u of the element pad 420 may be spaced apart from each other by a predetermined distance d along a direction Z perpendicular to the upper surface 110u of the first insulating layer 110. In addition, a height h1 of the upper surface 300u of the first conductive pad 300 may be higher than a height h2 of the upper surface 420u of the element pad 420 based on the upper surface 410u of the element main body 410.

In addition, the upper surface 300u of the first conductive pad 300 may be higher than the upper surface 110u of the first insulating layer 110, and the upper surface 420u of the element pad 420 may be lower than upper surface 100u of the first insulating layer 110.

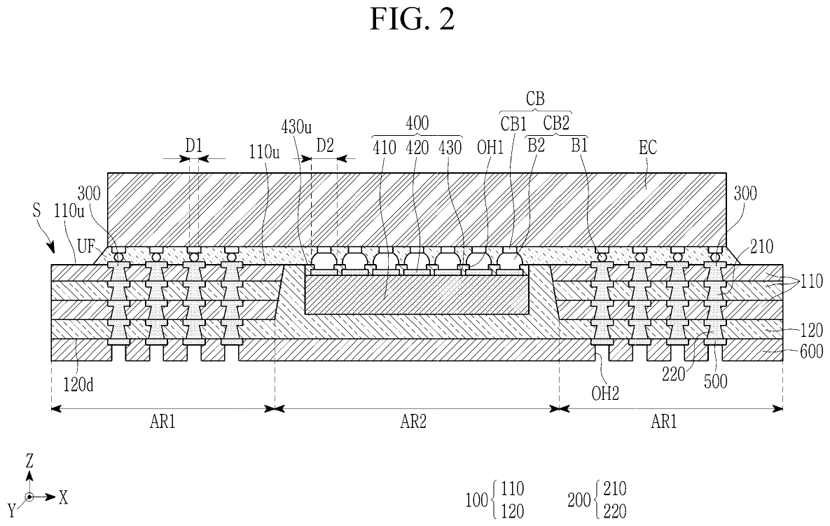

Accordingly, a step may be formed between the element pad 420 of the circuit element 400 directly electrically connected to an electronic component EC (see FIG. 2) and the first conductive pad 300 of a circuit board S. In addition, a width W2 of the element pad 420 may be wider than a width W1 of the first conductive pad 300. Accordingly, bonding reliability of a conductive adhesive member CB may be secured by making an amount of a second adhesive member B2 adhered to the element pad 420 larger than an amount of a first adhesive member B1 adhered to the first conductive pad 300.

The element insulating layer 430 may be disposed on the element main body 410, and may cover and protect the element main body 410. The element insulating layer 430 may have a first opening OH1 exposing the element pad 420. An upper surface 430u of the element insulating layer 430 may be disposed on the same plane as the upper surface 110u of the first insulating layer 110. As described above, since the element pad 420 embedded in the insulating layer 100 is exposed to the outside through the first opening OH1 of the element insulating layer 430, the circuit element 400 may be directly connected to a wire of the electronic component EC. Accordingly, reliability of the circuit element 400 may be easily secured.

In addition, a thickness of the circuit board S may be minimized by embedding passive elements in a thin coreless substrate including the insulating layer 100 and the circuit wire 200. Accordingly, thinning of an electronic component package including the circuit board S may be easily implemented.

The second conductive pad 500 may be connected to the second circuit wire 220, and may protrude from a lower surface 120d of the second insulating layer 120.

The first solder resist layer 600 may have a second opening OH2 that covers the lower surface 120d of the second insulating layer 120, and overlaps the second conductive pad 500. The first solder resist layer 600 may include an insulating material such as a solder resist.

Hereinafter, an electronic component package including the circuit board of FIG. 1 will be described in detail with reference to a drawing.

FIG. 2 illustrates a cross-sectional view of an electronic component package including the circuit board of FIG. 1.

As shown in FIG. 2, the electronic component package according to the embodiment includes the circuit board S, the electronic component EC, the conductive adhesive member CB, and an underfill UF.

The circuit board S includes the insulating layer 100, the circuit wire 200, the first conductive pad 300, the circuit element 400, the second conductive pad 500, and the first solder resist layer 600. Since a detailed description of the circuit board S is described above, a detailed description thereof will be omitted.

The electronic component EC may be an integrated circuit die in which hundreds to millions of elements are integrated into a single chip. For example, the electronic component EC may be a processor chip such as a central processor (for example, a CPU), a graphics processor (for example, a GPU), a field programmable gate array (FPGA), a digital signal processor, a cryptographic processor, a microprocessor, a microcontroller, and the like. In some embodiments, the electronic component EC may be an application processor (AP), but is not limited thereto. In some embodiments, the electronic component EC may be a memory such as an other volatile memory (for example, a DRAM), a non-volatile memory (for example, a ROM), and a flash memory, an analog-to-digital converter, or a logic such as an application-specific IC (ASIC).

The conductive adhesive member CB may electrically connect the electronic component EC and the first conductive pad 300. The conductive adhesive member CB may include a bump CB1 disposed to cover a signal wire of the electronic component EC, and an auxiliary adhesive member CB2 positioned between the bump CB1 and the first conductive pad 300 to improve adhesion and conductivity. The bump CB1 may include at least one conductive material selected from the group consisting of copper (Cu), aluminum (Al), silver (Ag), tin (Sn), gold (Au), nickel (Ni), lead (Pb), titanium (Ti), and an alloy thereof. The auxiliary adhesive member CB2 may include solder or the like. In the present embodiment, the bump CB1 is a pillar shape, but is not necessarily limited thereto, and a ball shape bump is possible.

The auxiliary adhesive member CB2 may include a first adhesive member B1 and a second adhesive member B2. The first adhesive member B1 may adhere the bump CB1 and the first conductive pad 300 to each other, and the second adhesive member B2 may adhere the bump CB1 and the element pad 420 to each other.

In this case, a height h1 of the upper surface 300u of the first conductive pad 300 based on the upper surface 410u of the element main body 410 is higher than a height h2 of the upper surface 420u of the element pad 420, and a width W2 of the element pad 420 is wider than a width W1 of the first conductive pad 300, so that a maximum width D2 of a second adhesive member B2 adhered to the element pad 420 may be larger than a maximum width D1 of a first adhesive member B1 adhered to the first conductive pad 300.

Accordingly, in a structure in which the height h1 of the upper surface 300u of the first conductive pad 300 is higher than the height h2 of the upper surface 420u of the element pad 420, based on the upper surface 410u of the element main body 410, a surface area of the second adhesive member B2 adhered to the element pad 420 may be larger than a surface area of the first adhesive member B1 adhered to the first conductive pad 300.

As such, by forming a step between the element pad 420 of the circuit element 400 directly and electrically connected to the electronic component EC and the first conductive pad 300 of the circuit board S, the reliability of the conductive adhesive member CB may be ensured by allowing the surface are of the second adhesive member B2 adhered to the element pad 420 to be larger than the surface area of the first adhesive member B1 adhered to the first conductive pad 300.

The underfill UF is filled between the electronic component EC and the insulating layer 100, and may fix the electronic component EC.

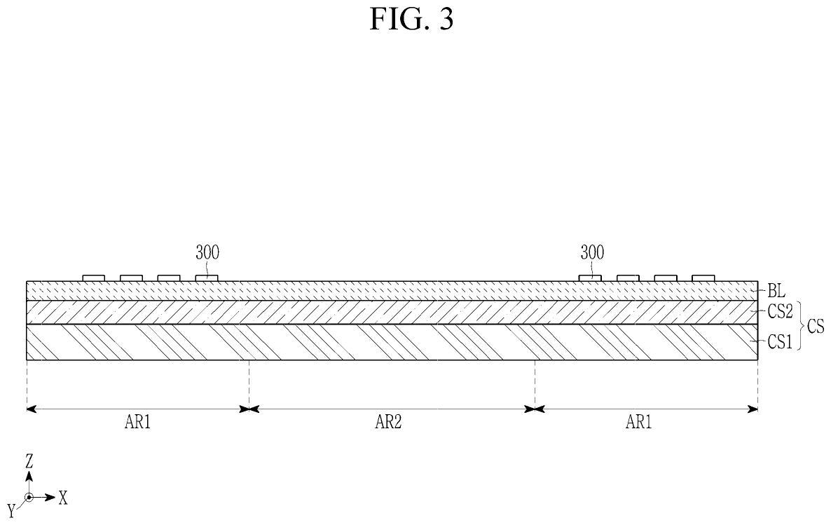

Hereinafter, with reference to FIG. 3 to FIG. 7 together with FIG. 1, a manufacturing method of a circuit board according to an embodiment will be described in detail.

FIG. 3 to FIG. 7 illustrate sequential cross-sectional views of a manufacturing method of a circuit board according to some embodiments of the present disclosure.

As shown in FIG. 3, a barrier layer BL is formed on a carrier substrate CS, and the first conductive pad 300 is formed on the barrier layer BL. The carrier substrate CS may be a substrate that may be separated from the barrier layer BL in a subsequent process.

The carrier substrate CS may include a carrier film CS1, and a release layer CS2 disposed on the carrier film CS1. The carrier film CS1 may include a copper clad laminate or the like. The release layer CS2 may be separated from the barrier layer BL by a predetermined external force. The release layer CS2 may be made of a different material from that of the barrier layer BL. For example, the release layer CS2 may include at least one selected from the group consisting of chromium (Cr), nickel (Ni), zinc (Zn), molybdenum (Mo), tungsten (W), cobalt (Co), lead (Pb), silver (Ag), tantalum (Ta), copper (Cu), aluminum (Al), manganese (Mn), iron (Fe), titanium (Ti), tin (Sn), steel, vanadium (V), and a combination thereof. The first conductive pad 300 may be formed at a position corresponding to the first area AR1, which is different from the second area AR2, in which the first insulating layer 110 and a cavity CA are to be formed in a subsequent process.

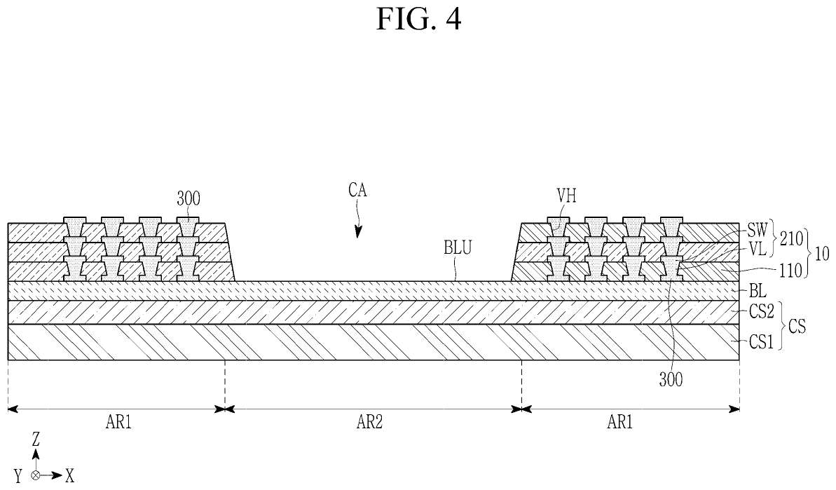

As shown in FIG. 4, the first insulating layer 110 is formed on the barrier layer BL to cover the first conductive pad 300. Then, a via hole VH exposing the first conductive pad 300 is formed in the first insulating layer 110 by using a photolithography process, and the via hole VH is filled to form the first circuit wire 210 including a via layer VL. A side surface of the via layer VL may be formed in a reverse tapered shape. The first circuit wire 210 may be formed in the second area AR2 inside the first insulating layer 110. Here, the first insulating layer 110 and the first circuit wire 210 together constitute a first layer unit 10. Then, the first layer unit 10 may be repeatedly stacked. In the embodiment illustrated FIG. 4, three first layer units 10 are formed, but the present disclosure is not limited thereto, and a variable number of the first layer unit 10 may be formed.

In addition, a via hole VH may be formed in the first insulating layer disposed on an uppermost portion of the first insulating layer 110, and a cavity CA exposing an upper surface BLU of the barrier layer BL may be formed. The cavity CA may be formed in the second area AR2 inside the first insulating layer 110.

As such, since the cavity CA may be simultaneously formed in the process of forming the via hole VH without performing a separate process for forming the cavity CA for disposing the circuit element 400, the manufacturing process may be simplified to reduce manufacturing costs.

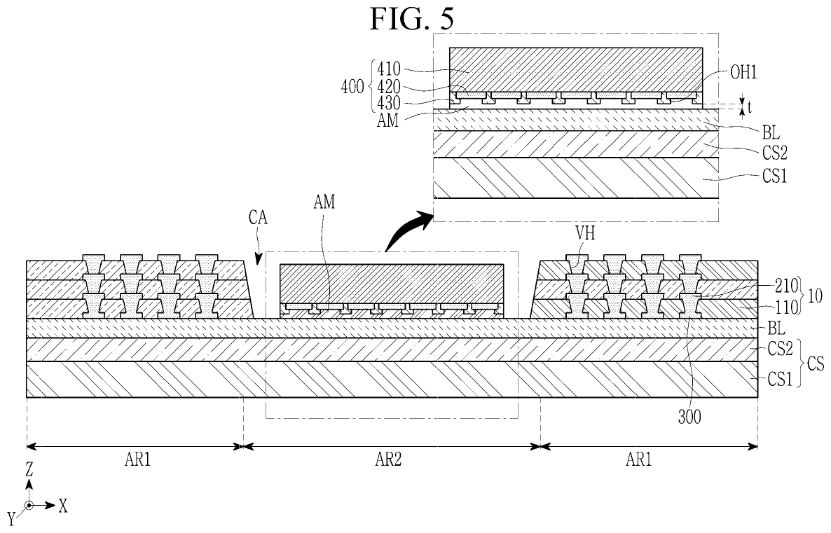

As shown in FIG. 5, the circuit element 400 may be disposed in the cavity CA, and the element pad 420 of the circuit element 400 may be adhered to the barrier layer BL by using an adhesive member AM. In this case, the adhesive member AM may also be adhered to the element insulating layer 430. By adjusting a thickness (t) of the adhesive member AM, a predetermined interval (d) between an extension line of the upper surface 300u of the first conductive pad 300 and the upper surface 420u of the element pad 420 may be adjusted. Accordingly, a step between the element pad 420 of the circuit element 400 directly electrically connected to the electronic component EC and the first conductive pad 300 of the circuit board S may be easily adjusted.

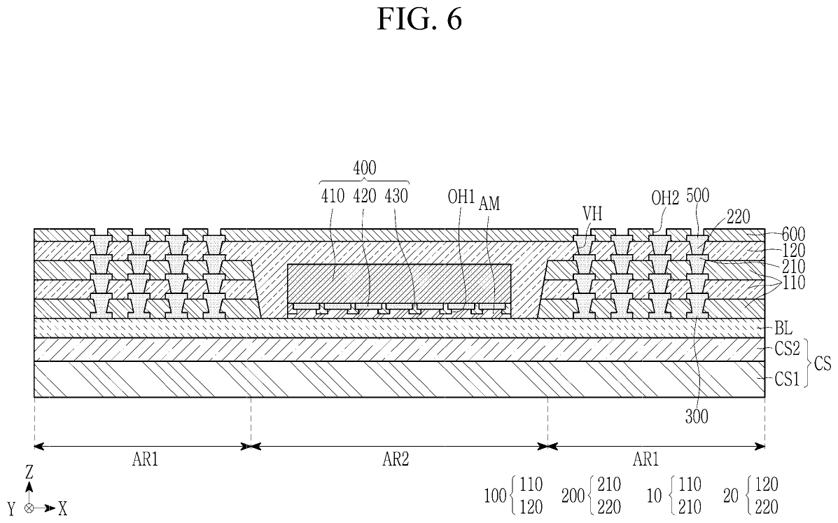

As shown in FIG. 6, the second insulating layer 120 filling the cavity CA on the first layer unit and covering the first circuit wire 210 is formed. Then, the via hole VH exposing the first circuit wire 210 is formed in the second insulating layer 120 by using a photo etching process, and the second circuit wire 220 filling the via hole VH is formed. Here, the second insulating layer 120 and the second circuit wire 220 together form a second layer unit 20. In the present embodiment, one second layer unit 20 is formed, but is not limited thereto, and by repeatedly stacking the second layer unit 20, various numbers of the second layer units 20 may be formed.

In addition, the second conductive pad 500 connected to the second circuit wire 220 may be formed on the second insulating layer 120. The second conductive pad 500 may be made of the same material as the second circuit wire 220. In addition, the first solder resist layer 600 having a second opening OH2 exposing the second conductive pad 500 is formed on the second insulating layer 120. The second opening OH2 may be formed by performing processes such as exposure, hardening, and development on the first solder resist layer 600 by using a mask.

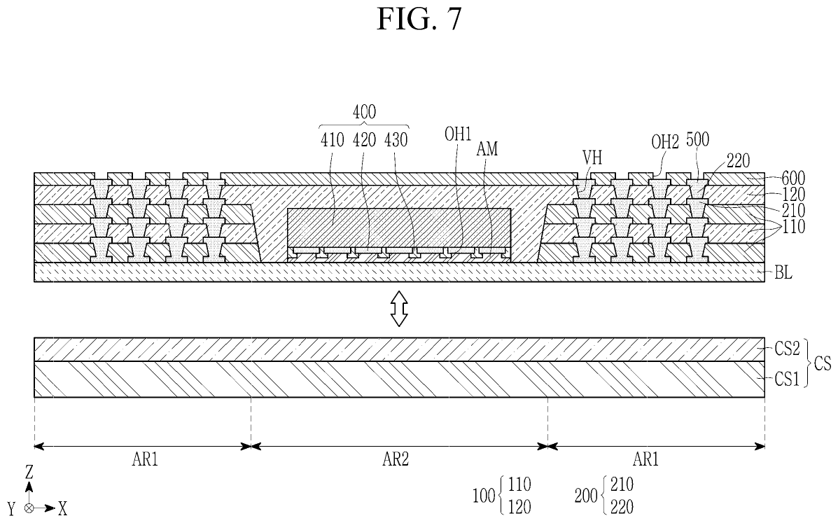

As shown in FIG. 7, the carrier substrate CS is separated from the barrier layer BL. Since the release layer CS2 of the carrier substrate CS is made of a different material from that of the barrier layer BL, the release layer CS2 may be easily separated from the barrier layer BL.

As shown in FIG. 1, the circuit board S is turned over. Then, the barrier layer BL, the adhesive member AM, and the upper surface 110u of the first insulating layer 110 are sequentially etched to have the first conductive pad 300 protrude above the upper surface 110u of the first insulating layer 110. In this case, since the element insulating layer 430 and the first insulating layer 110 are simultaneously etched, the upper surface 430u of the element insulating layer 430 may be disposed on the same plane as the upper surface 110u of the first insulating layer 110.

Meanwhile, in some embodiments, only the first solder resist layer protecting the second conductive pad is formed, while another embodiment in which the second solder resist layer protecting the first conductive pad is formed is also possible.

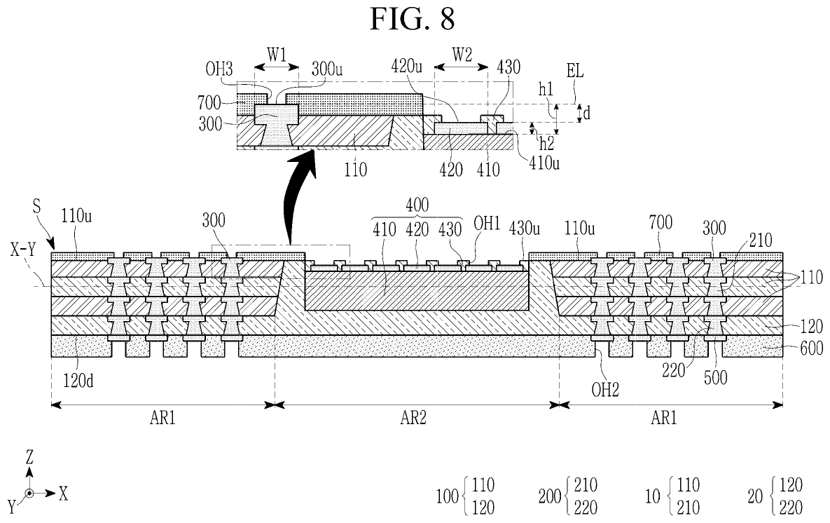

Hereinafter, with reference to FIG. 8, a circuit board according to another embodiment will be described in detail.

FIG. 8 illustrates a cross-sectional view of a circuit board according to another embodiment.

The embodiment shown in FIG. 8 is substantially the same as the embodiment shown in FIG. 1, except for the second solder resist layer. Thus, a repeated description thereof will be omitted.

As shown in FIG. 8, a circuit board according to another embodiment includes an insulating layer 100, a circuit wire 200, a first conductive pad 300, a circuit element 400, a second conductive pad 500, a first solder resist layer 600, and a second solder resist layer 700.

The second solder resist layer 700 may be disposed on the upper surface 110u of the first insulating layer 110 to protect the first insulating layer 110. The second solder resist layer 700 may have a third opening OH3 exposing the first conductive pad 300. Accordingly, the first conductive pad 300 exposed through the third opening OH3 may be electrically connected to the signal wire of the electronic component EC through the conductive adhesive member CB.

While the desirable embodiments of the present disclosure have been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

| | |
|---|---|
| 100: insulating layer | 200: circuit wire |
| 300: first conductive pad | 400: circuit element |
| 410: element main body | 420: element pad |
| 430: element insulating layer | 500: second conductive pad |
| 600: first solder resist layer | 700: second solder resist layer |

What is claimed is:

1. A circuit board comprising:
an insulating layer including a first area and a second area;
a circuit wire disposed inside the first area of the insulating layer;
a first conductive pad connected to the circuit wire and having an upper surface protruding above an upper surface of the insulating layer and a lower surface embedded in the insulating layer; and
a circuit element including an element pad and disposed inside the second area of the insulating layer,
wherein an extension line of an upper surface of the first conductive pad and an upper surface of the element pad are spaced apart from each other along a direction perpendicular to an upper surface of the insulating layer, and
based on a direction perpendicular to the upper surface of the insulating layer, the upper surface of the first conductive pad is disposed on the upper surface of the insulating layer, and the upper surface of the element pad is disposed below the upper surface of the insulating layer.

2. The circuit board of claim 1, wherein
a layer on which the circuit element is disposed in the second area and a layer on which a portion of the circuit wire is disposed in the first area are disposed on the same layer.

3. The circuit board of claim 1, wherein
a width of the element pad is wider than a width of the first conductive pad.

4. The circuit board of claim 3, wherein
the circuit element further includes
an element main body having an upper surface on which the element pad is disposed, and
an element insulating layer disposed on the upper surface of the element main body and having a first opening exposing at least a part of the element pad.

5. The circuit board of claim 4, wherein
based on the upper surface of the element main body, a height of an upper surface of the first conductive pad is higher than a height of an upper surface of the element pad.

6. The circuit board of claim 4, wherein
the circuit element is disposed to have a boundary surface parallel to the upper surface of the insulating layer in the second area, and
at least a portion of the circuit wire is disposed on the same layer as the boundary surface.

7. The circuit board of claim 4, further comprising
a second conductive pad connected to the circuit wire and protruding downwardly from a lower surface of the insulating layer, and
a first solder resist layer covering the lower surface of the insulating layer and having a second opening exposing at least a part of the second conductive pad.

8. The circuit board of claim 7, further comprising
a second solder resist layer covering the upper surface of the insulating layer and having a third opening exposing at least a part of the first conductive pad.

9. The circuit board of claim 1, wherein
the circuit element includes an integrated passive element.

10. A method of manufacturing a circuit board, comprising:
sequentially forming a barrier layer on a carrier substrate and a first conductive pad on the barrier layer;
disposing a first layer unit on a part of the barrier layer to cover the first conductive pad, and including a first insulating layer and a first circuit wire disposed within the first insulating layer, wherein a cavity is formed at an area where the first layer unit is not disposed on the barrier layer;
disposing a circuit element including an element pad on a bottom surface of the circuit element in the cavity,
adhering the element pad of the circuit element to the barrier layer by using an adhesive member disposed between the element pad and the barrier layer;
forming a second layer unit including a second insulating layer filling the cavity on the first layer unit and a second circuit wire disposed within the second insulating layer;
separating the carrier substrate from the barrier layer; and
sequentially etching the barrier layer, the adhesive member, and the upper surface of the first insulating layer to have the first conductive pad protrude above the upper surface of the first insulating layer.

11. The method of manufacturing the circuit board of claim 10, wherein
the adhesive member covers the element main body, and adheres an element insulating layer having a first opening exposing the element pad, and the barrier layer.

12. The method of manufacturing the circuit board of claim 10, further comprising
forming a second conductive pad connected to the second circuit wire on the second insulating layer, and
forming a first solder resist layer having a second opening exposing the second conductive pad on the second insulating layer.

13. The method of manufacturing the circuit board of claim 10, wherein
a width of the element pad is wider than a width of the first conductive pad.

14. The method of manufacturing the circuit board of claim 10, wherein
a cavity is formed in the first layer unit to expose the barrier layer.

15. An electronic component package, comprising:
a circuit board including an insulating layer having a first area and a second area;
a circuit wire disposed in the first area inside the insulating layer;
a first conductive pad connected to the circuit wire and having an upper surface protruding above an upper surface of the insulating layer and a lower surface embedded in the insulating layer;
a circuit element including an element pad disposed inside and at the second area of the insulating layer;
an electronic component disposed on the circuit board; and
a conductive adhesive member disposed on the electronic component and electrically connected to the first conductive pad and the element pad,
wherein an extension line of an upper surface of the first conductive pad and an upper surface of the element pad are spaced apart from each other along a direction perpendicular to an upper surface of the insulating layer, and
based on a direction perpendicular to the upper surface of the insulating layer, the upper surface of the first conductive pad is higher than the upper surface of the insulating layer, and the upper surface of the element pad is lower than the upper surface of the insulating layer.

16. The electronic component package of claim 15, wherein
the conductive adhesive member includes
a bump disposed to cover a signal wire of the electronic component,
a first adhesive member that adheres the bump and the first conductive pad to each other, and
a second adhesive member that adheres the bump and the element pad to each other, and
a maximum width of the second adhesive member is wider than a maximum width of the first adhesive member.

17. The electronic component package of claim 15, wherein
a layer on which the circuit element is disposed in the second area and a layer on which a portion of the circuit wire is disposed in the first area are disposed on the same layer.

18. The electronic component package of claim 15, wherein
a width of the element pad is wider than a width of the first conductive pad.
